(19) United States
(12) Patent Application Publication
(10) Pub. No.: US 2025/0234438 A1
(43) Pub. Date: Jul. 17, 2025

(54) LIGHT EMITTING DEVICE AND DISTANCE MEASURING DEVICE

(71) Applicant: SONY SEMICONDUCTOR SOLUTIONS CORPORATION, KANAGAWA (JP)

(72) Inventor: KUNIHIKO IZUHARA, KANAGAWA (JP)

(21) Appl. No.: 18/702,813

(22) PCT Filed: Oct. 17, 2022
(86) PCT No.: PCT/JP2022/038584

§ 371 Date: Apr. 19, 2024

(30) Foreign Application Priority Data
Oct. 29, 2021 (JP) 2021-178297

(51) Int. Cl. H05B 45/345; G01S 7/484; G01S 17/10; H05B 47/155; H05B 47/16

(52) U.S. Cl. CPC H05B 45/345; G01S 7/484; G01S 17/10; H05B 47/155; H05B 47/16

(57) ABSTRACT

To reduce power consumption of a light emitting device. The light emitting device includes a plurality of light emitting elements, a plurality of driving thyristors, a selection unit, a light emission current supply unit, and a current adjustment unit. The driving thyristors are disposed for each of the plurality of light emitting elements and become conductive themselves to thereby feed a light emission current to the light emitting elements ad drive the light emitting elements. The selection unit includes a plurality of selection thyristors that are disposed for each of the plurality of driving thyristors and output a conduction signal for making the driving thyristors conductive when the selection thyristors become conductive themselves and alternately repeats a transfer period for sequentially selecting the plurality of driving thyristors by shifting, in order, a position of the selection thyristor coming into a conduction state among the plurality of selection thyristors and a driving period for causing the selected driving thyristor to drive the light emitting element. The light emission current supply unit supplies a light emission current to the light emitting element via the selected driving thyristor in the driving period. The current adjustment unit supplies a conduction current of the selection thyristor and adjusts the conduction current of the selection thyristor in the driving period.

### FIELD

The present disclosure relates to a light emitting device and a distance measuring device.

### BACKGROUND

A distance measuring device that irradiates an object such as a subject with light, detects reflected light reflected from the object, and measures a distance to the object is used. In such a distance measuring device, a light emitting device with high luminance is required to cope with a distant object. As this light emitting device, a light emitting device using a laser diode has been proposed. For example, a light emitting device including a plurality of laser diodes and a plurality of setting thyristors for setting light emission or non-light emission of each of the laser diodes has been proposed (see, for example, Patent Literature 1.).

In this light emitting device, a plurality of transfer thyristors that are disposed for each of the plurality of setting thyristors and sequentially select and make the setting thyristors conductive are used. The plurality of transfer thyristors configure a shift register. The transfer thyristors sequentially come into a conduction state and the setting thyristors are sequentially selected.

### CITATION LIST

### Patent Literature

Patent Literature 1: JP 2020-120018 A

### SUMMARY

### Technical Problem

However, in the related art described above, since an electric current for maintaining the conduction state of the transfer thyristors and the set thyristors flows, there is a problem in that power consumption increases.

Therefore, the present disclosure proposes a light emitting device and a distance measuring device that reduce power consumption.

### Solution to Problem

A light emitting device according to the present disclosure includes: a plurality of light emitting elements; a plurality of driving thyristors that are disposed for each of the plurality of light emitting elements and become conductive themselves to thereby feed a light emission current to the light emitting elements and drive the light emitting elements; a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor; a light emission current supply unit that supplies the light emission current to the light emitting element via the selected driving thyristor in the driving period; and a current adjustment unit that supplies a conduction current of the selection thyristor and adjusts the conduction current of the selection thyristor in the driving period.

### BRIEF DESCRIPTION OF DRAWINGS

FIG. 1 is a diagram illustrating a configuration example of a light emitting device according to an embodiment of the present disclosure.

FIG. 2 is a diagram illustrating a configuration example of a thyristor according to the embodiment of the present disclosure.

FIG. 3A is a diagram illustrating an example of a driving method according to the embodiment of the present disclosure.

FIG. 3B is a diagram illustrating the example of the driving method according to the embodiment of the present disclosure.

FIG. 4A is a diagram illustrating the example of the driving method according to the embodiment of the present disclosure.

FIG. 4B is a diagram illustrating the example of the driving method according to the embodiment of the present disclosure.

FIG. 5A is a diagram illustrating the example of the driving method according to the embodiment of the present disclosure.

FIG. 5B is a diagram illustrating the example of the driving method according to the embodiment of the present disclosure.

FIG. 6A is a diagram illustrating the example of the driving method according to the embodiment of the present disclosure.

FIG. 6B is a diagram illustrating the example of the driving method according to the embodiment of the present disclosure.

FIG. 7A is a diagram illustrating the example of the driving method according to the embodiment of the present disclosure.

FIG. 7B is a diagram illustrating the example of the driving method according to the embodiment of the present disclosure.

FIG. 8A is a diagram illustrating the example of the driving method according to the embodiment of the present disclosure.

FIG. 8B is a diagram illustrating the example of the driving method according to the embodiment of the present disclosure.

FIG. 9A is a diagram illustrating the example of the driving method according to the embodiment of the present disclosure.

FIG. 9B is a diagram illustrating the example of the driving method according to the embodiment of the present disclosure.

FIG. 10A is a diagram illustrating the example of the driving method according to the embodiment of the present disclosure.

FIG. 10B is a diagram illustrating the example of the driving method according to the embodiment of the present disclosure.

FIG. 11 is a diagram illustrating a configuration example of a light emitting device according to a first embodiment of the present disclosure.

FIG. 12 is a diagram illustrating an example of a driving method according to the first embodiment of the present disclosure.

FIG. 13 is a diagram illustrating another configuration example of the light emitting device according to the first embodiment of the present disclosure.

FIG. 14 is a diagram illustrating a configuration example of a light emitting device according to a second embodiment of the present disclosure.

FIG. 15 is a diagram illustrating an example of a driving method according to the second embodiment of the present disclosure.

FIG. 16 is a diagram illustrating another example of the driving method according to the second embodiment of the present disclosure.

FIG. 17 is a diagram illustrating a configuration example of a distance measuring device according to an embodiment of the present disclosure.

FIG. 18A is a diagram illustrating an example of a distance measuring method according to an embodiment of the present disclosure.

FIG. 18B is a diagram illustrating an example of the distance measuring method according to the embodiment of the present disclosure.

### DESCRIPTION OF EMBODIMENTS

Embodiments of the present disclosure are explained in detail below with reference to the drawings. Explanation is made in the following order. Note that, in the embodiments explained below, redundant explanation is omitted by denoting the same parts with the same reference numerals and signs.
1. Basic Configuration
2. First Embodiment
3. Second Embodiment
4. Configuration of a distance measuring device

### 1. Basic Configuration

### [Configuration of a Light Emitting Device]

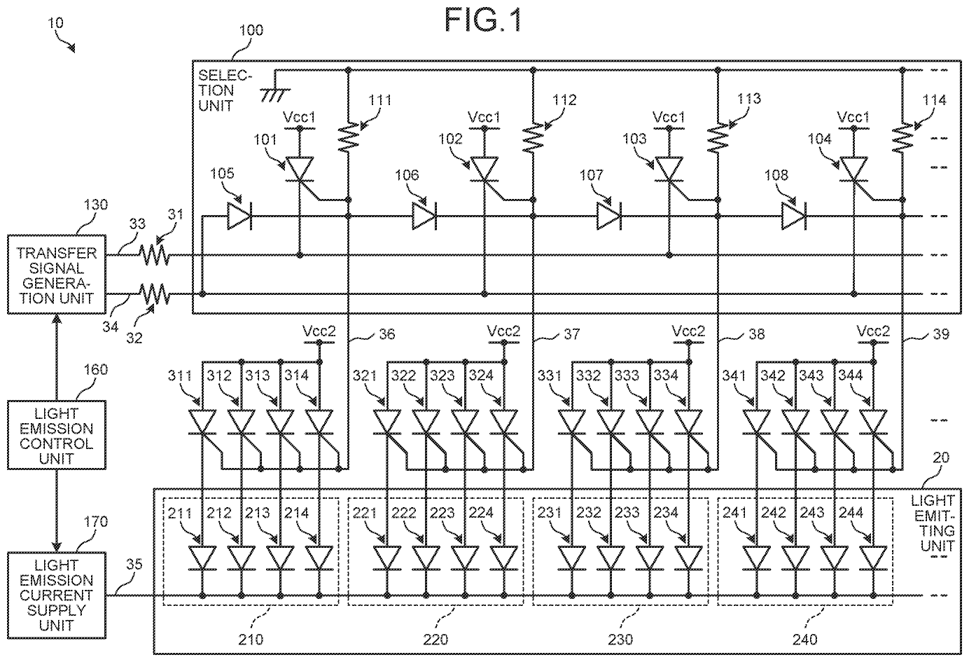

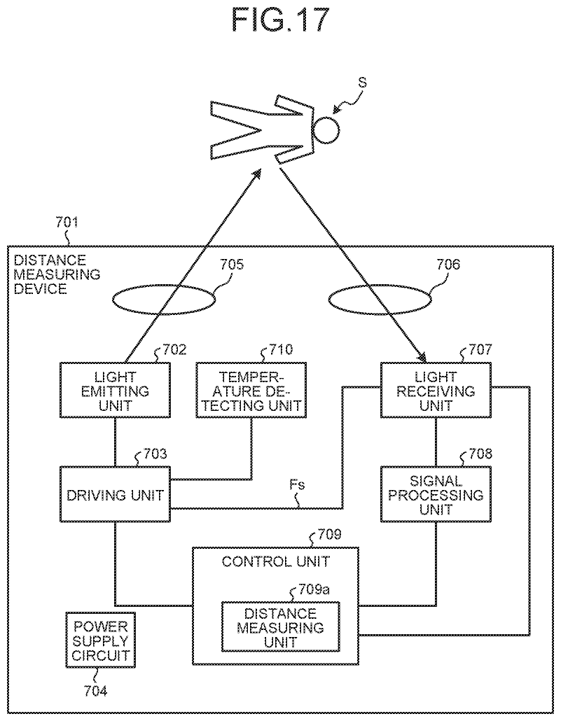

FIG. 1 is a diagram illustrating a configuration example of a light emitting device according to an embodiment of the present disclosure. FIG. 1 is a block diagram illustrating a configuration example of a light emitting device 10. The light emitting device 10 is a device that irradiates a subject with light. A device used for a distance measuring device 701 explained below with reference to FIG. 17 is assumed as the light emitting device 10.

The light emitting device 10 illustrated in the figure includes driving thyristors 311 to 314, 321 to 324, 331 to 334, and 341 to 344, a selection unit 100, resistors 31 and 32, a transfer signal generation unit 130, a light emission current supply unit 170, and a light emission control unit 160. A light emitting unit 20 is further illustrated in the figure.

The light emitting unit 20 includes a plurality of light emitting elements and emits light for irradiating an object such as a subject. The light emitting unit 20 illustrated in the figure represents an example in which laser diodes are used as light emitting elements. The light emitting unit 20 in illustrated in the figure includes light emitting elements 211 to 214, 221 to 224, 231 to 234, and 241 to 244. Note that the light emitting elements 211 to 214, 221 to 224, 231 to 234, and 241 to 244 respectively configure light emitting element groups 210, 220, 230, and 240. The respective light emitting elements configuring the light emitting element group 210 and the like are simultaneously driven to emit light.

Cathodes of the light emitting elements 211 to 214, 221 to 224, 231 to 234, and 241 to 244 are connected to a signal line 35. Anodes of the respective light emitting elements 211 to 214, 221 to 224, 231 to 234, and 241 to 244 are respectively connected to cathodes of the driving thyristors 311 to 314, 321 to 324, 331 to 334, and 341 to 344.

The driving thyristors 311 to 314, 321 to 324, 331 to 334, and 341 to 344 are disposed in the light emitting element 211 and the like as described above. The driving thyristor 311 and the like are connected to the light emitting element 211 and the like and become conductive themselves to feed a light emission current to the light emitting element 211 and the like to drive the light emitting element 211 and the like. The driving thyristors 311 to 314, 321 to 324, 331 to 334, and 341 to 344 respectively correspond to the light emitting element groups 210, 220, 230, and 240 and simultaneously drive the light emitting elements included in the respective light emitting element groups. For the driving thyristors 311 to 314, 321 to 324, 331 to 334, and 341 to 344 illustrated in the figure, a thyristor configured by a gallium-arsenic (GaAs) compound semiconductor can be used and a p-gate thyristor can be used. Details of the driving thyristor 311 and the like are explained below.

Anodes of the driving thyristors 311 to 314, 321 to 324, 331 to 334, and 341 to 344 are connected to a power supply line Vcc2 in common. Gates of the driving thyristors 311 to 314 are connected to a signal line 36. Gates of the driving thyristors 321 to 324 are connected to a signal line 37 in common. Gates of the driving thyristors 331 to 334 are connected to a signal line 38 in common. Gates of the driving thyristors 341 to 344 are connected to a signal line 39 in common. A conduction signal for conducting the driving thyristor 311 and the like is output from the selection unit 100 to the signal lines 36 to 39. Note that the power supply line Vcc2 is a power supply line for supplying a power supply voltage for the light emitting element 211 and the like.

The selection unit 100 selects a driving thyristor. The selection unit 100 illustrated in the figure selectively outputs a conduction signal to each of the driving thyristor groups such as the driving thyristors 311 to 314 corresponding to a light emitting element group. The selection unit 100 includes selection thyristors 101 to 104, diodes 105 to 108, and resistors 111 to 114.

Anodes of the selection thyristors 101 to 104 are connected to the power supply line Vcc1 in common. Gates of the selection thyristors 101 to 104 are respectively connected to signal lines 36 to 39. Sources of the selection thyristors 101 and 103 are connected to one end of the resistor 31 in common. The other end of the resistor 31 is connected to the signal line 33. Sources of the selection thyristors 102 and 104 and the anode of the diode 105 are connected to one end of the resistor 32 in common. The other end of the resistor 32 is connected to the signal line 34. The cathode of the diode 105 is connected to the signal line 36.

The anode of the diode 106 is connected to the signal line 36 and the cathode of the diode 106 is connected to the signal line 37. The anode of the diode 107 is connected to the signal line 37 and the cathode of the diode 107 is connected to the signal line 38. The anode of the diode 108 is connected to the signal line 38 and the cathode of the diode 108 is connected to the signal line 39. One end of the resistor 111 is connected to the signal line 36 and the other end of the resistor 111 is grounded. One end of the resistor 112 is connected to the signal line 37 and the other end of the resistor 112 is grounded. One end of the resistor 113 is connected to the signal line 38 and the other end of the resistor 113 is grounded. One end of the resistor 114 is connected to the signal line 39 and the other end of the resistor 114 is grounded. Note that the power supply line Vcc1 is a power supply line that supplies a power supply voltage to the selection unit 100.

The selection thyristors 101 to 104 output conduction signals for the driving thyristor 311 and the like. The selection thyristors 101 to 104 output, as the conduction signals, gate voltages at the time when the selection thyristors 101 to 104 become conductive. For the selection thyristor 101 and the like, a thyristor configured by a GaAs compound semiconductor can be used and a p-gate thyristor can be used.

The diodes 105 to 108 transmit gate voltages for conducting the selection thyristor 101 and the like. For the diode 105 and the like, a diode configured by a GaAs compound semiconductor can be used.

The resistors 111 to 114 are resistors that transmit ground potential to the gates of the selection thyristor 101 and the like.

The signal lines 33 and 34 are signal lines for transmitting transfer signals (transfer signals ϕ1 and ϕ2) from the transfer signal generation unit 130. The selection unit 100 is driven by these transfer signals. Specifically, the selection unit 100 alternately repeats a driving period in which any one of the selection thyristors 101 to 104 is made conductive and a driving signal is output to the driving thyristor 311 or the like corresponding to the selection thyristor made conductive and a transfer period in which the selection thyristors 101 to 104 are selected. In this transfer period, gate voltages are sequentially transferred and driving for shifting, in order, the position of the selection thyristor 101 and the like coming into a conduction state among the selection thyristors 101 to 104 is performed. Details of an operation of the selection unit 100 are explained below.

The transfer signal generation unit 130 generates the transfer signals explained above. The transfer signal generation unit 130 illustrated in the figure generates the transfer signals ϕ1 and ϕ2 and outputs the transfer signals ϕ1 and ϕ2 respectively to the signal lines 33 and 34. Details of the transfer signals ϕ1 and ϕ2 are explained below.

The light emission current supply unit 170 supplies a light emission current to the light emitting element 211 and the like in the driving period explained above. The light emission current supply unit 170 supplies the light emission current in a light emission period in which the light emitting element 211 and the like are caused to emit light and stops the supply of the light emission current in a non-light emission period in which the light emission of the light emitting element 211 and the like is stopped. The light emission current supply unit 170 can alternately repeat the light emission period and the non-light emission period. For example, the light emission current supply unit 170 can supply the light emission current by applying a pulse-like driving signal to the light emitting element 211 and the like. This driving signal is applied via the signal line 35.

### [Configuration of a Thyristor]

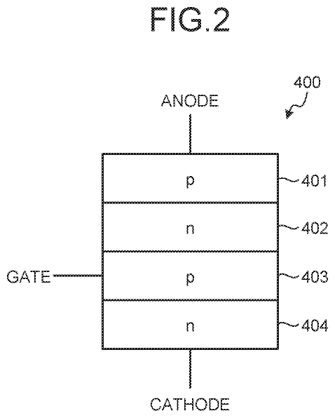

FIG. 2 is a diagram illustrating a configuration example of a thyristor according to the embodiment of the present disclosure. FIG. 2 is a diagram illustrating a configuration example of a thyristor 400 applicable as the driving thyristor 311 and the like, the selection thyristor 101 and the like. The thyristor 400 is a semiconductor element configured by sequentially joining an n-type semiconductor 404, a p-type semiconductor 403, an n-type semiconductor 402, and a p-type semiconductor 401. The n-type semiconductor 404, the p-type semiconductor 403, the n-type semiconductor 402, and the p-type semiconductor 401 can be configured by a GaAs compound semiconductor.

An anode electrode is disposed in the p-type semiconductor 401 and a cathode electrode is disposed in the n-type semiconductor 404. A gate electrode is disposed in the p-type semiconductor 403. By applying a high-potential gate voltage to the cathode, the anode and the cathode can be connected. Such a thyristor 400 is referred to as p-gate thyristor. In the thyristor 400 configured by the GaAs compound semiconductor, a threshold voltage of a gate voltage is approximately 1.5 V. In the thyristor 400 shifted to the conduction state, a holding current is defined as a minimum current for maintaining the conduction state. To transition the thyristor 400 in the conduction state to a non-conduction state, it is necessary to set an electric current flowing between the anode and the cathode to a current lower than the holding current.

Note that the thyristor in which the gate electrode is disposed in the n-type semiconductor 402 illustrated in the figure is referred to as n-gate thyristor. The n-gate thyristor can be made conductive by applying a gate voltage having a low potential to the anode. Such an n-gate thyristor can also be applied to the driving thyristor 311 and the like and the selection thyristor 101 and the like. In that case, it is necessary to invert the voltages of the anode and the cathode.

### [Driving Method]

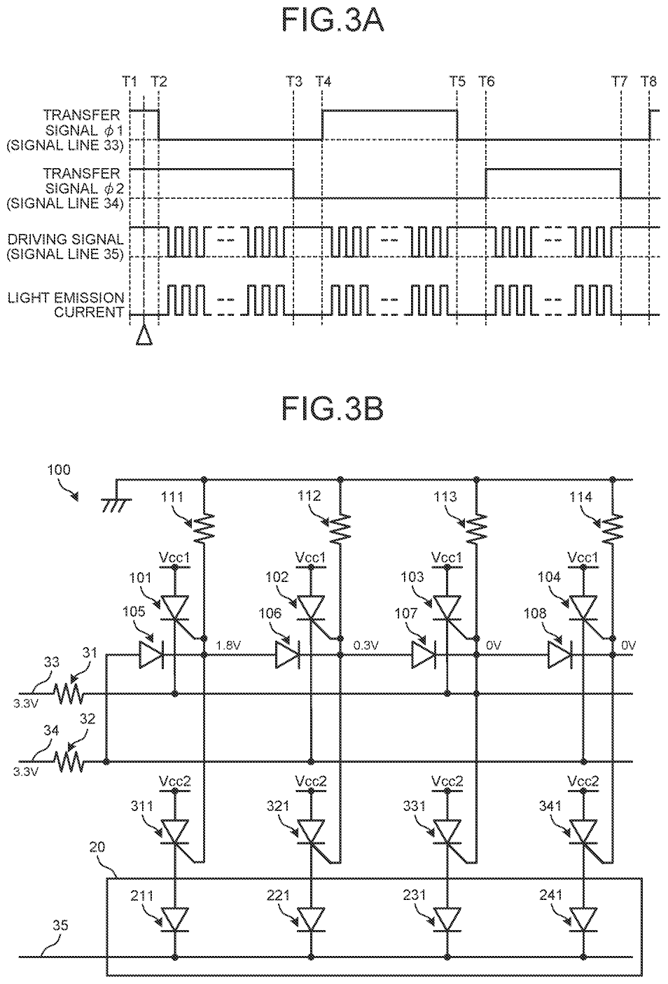

FIGS. 3A and 3B to FIGS. 10A and 10B are diagrams illustrating an example of a driving method according to the embodiment of the present disclosure. FIG. 3A to FIG. 10A are timing charts illustrating driving waveforms. FIG. 3B to FIG. 10B are circuit diagrams illustrating states of a circuit according to the timing charts of FIG. 3A to FIG. 10A.

In FIG. 3A to FIG. 10A, “transfer signal ϕ1” and “transfer signal ϕ2” represent binarized waveforms of the transfer signal ϕ1 and the transfer signal ϕ2 transferred via signal lines 33 and 34. “Driving signal” represents a waveform of a driving signal transmitted by the signal line 35. “Light emission current” represents a waveform of a light emission current flowing through the light emitting element 211 and the like. Note that a broken horizontal line represents potential of 0V. Note that power supply voltages of the power supply lines Vcc1 and Vcc2 are assumed to be 3.3 V. Note that, in FIG. 3A to FIG. 10A, a triangle represents a current position in the timing charts.

FIG. 3B to FIG. 10B are circuits obtained by simplifying the circuit illustrated FIG. 1 and illustrate an example of the light emitting unit 20 including the light emitting elements 211, 221, 231, and 241. In this case, the driving thyristors 311, 321, 331, and 341 are disposed. A forward voltage drop of the diode 105 and the like is assumed to be 1.5 V. A threshold of a gate voltage of the selection thyristor 101 and the like is assumed to be 1.5 V. A forward voltage drop of the selection thyristor 101 and the like is assumed to be 2.0 V. A light emission threshold voltage of a laser diode configuring the light emitting element 211 and the like is assumed to be 2.5 V.

T1 in FIG. 3A represents an initial state. In a period of T1 to T2, 3.3 V is applied to the transfer signals ϕ1 and ϕ2. 3.3 V is applied as a driving signal. In FIG. 3B, 3.3 V is applied to the signal lines 33 and 34. This voltage is transmitted by the diode 105 and the voltage of the gate of the selection thyristor 101 rises to 1.8 V. However, since the driving signal ϕ1 of 3.3 V is applied to the cathode via the resistor 31, the selection thyristor 101 maintains a non-conduction state. A gate voltage of the selection thyristor 102 is transmitted to the gate of the selection thyristor 101 by the diode 106 and rises to 0.3 V.

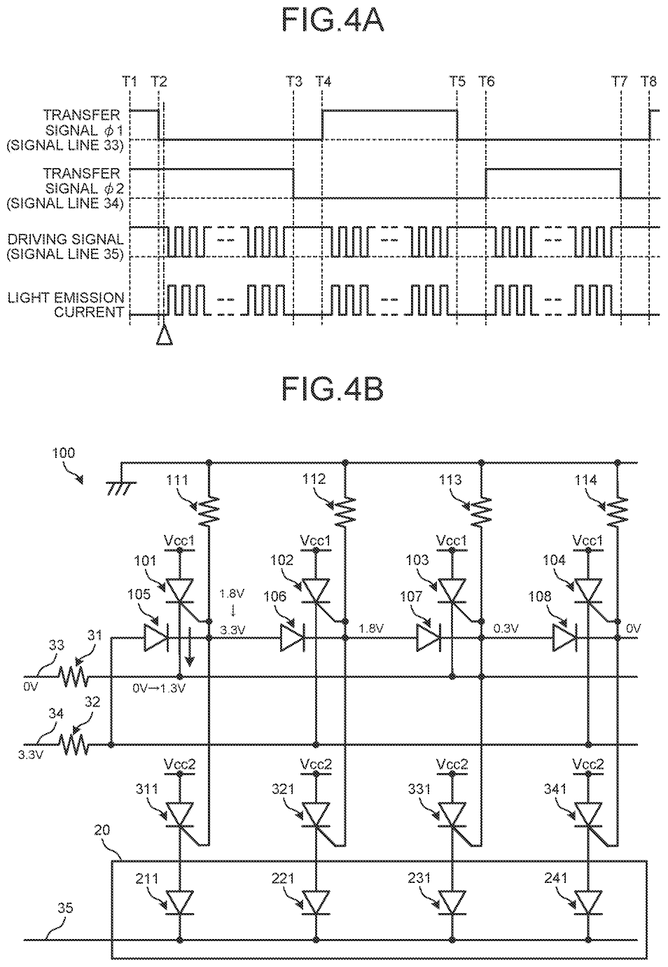

At T2 to T3 (see FIGS. 4A and 4B), the transfer signal ϕ1 changes to 0 V. Since the gate voltage is 1.5 V, the selection thyristor 101 comes into a conduction state. Then, since a cathode current of the selection thyristor 101 flows via the resistor 31, a terminal voltage of the resistor 31 rises and a cathode voltage of the selection thyristor 101 rises from 0 V to 1.3 V. According to the conduction of the selection thyristor 101, the gate voltage of the selection thyristor 101 rises to 3.3 V. This gate voltage is transmitted by the diode 106 and the gate voltage of the selection thyristor 102 changes to 1.8 V. However, since a cathode voltage of the selection thyristor 102 is 3.3 V, the selection thyristor 102 maintains a non-conduction state.

At T2 to T3, the driving thyristor 311 is selected by the selection thyristor 101. A gate voltage of 3.3 V is applied to the gate of the driving thyristor 311 as a conduction signal and the driving thyristor 311 comes into a conduction state. In this state, when a voltage of 0 V is applied as a driving signal, a light emission current flows to the light emitting element 211 via the driving thyristor 311. This figure illustrates an example in which a pulse train driving signal is applied. A light emission current flows in a pulse shape according to the pulse train driving signal.

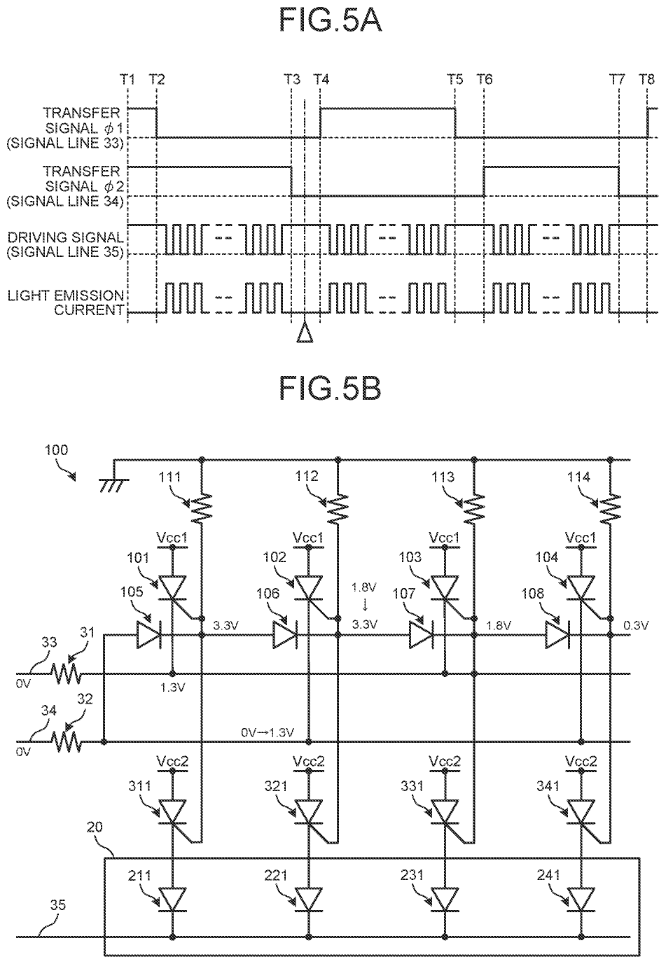

At T3 to T4 (see FIGS. 5A and 5B), since the transfer signal ϕ1 is 0 V, the selection thyristor 101 maintains the conduction state. The transfer signal ϕ2 changes to 0 V. Since the gate voltage is 1.8 V, the selection thyristor 102 comes into a conduction state. Then, since a cathode current of the selection thyristor 102 flows via the resistor 32, a terminal voltage of the resistor 32 rises and a cathode voltage of the selection thyristor 102 rises from 0 V to 1.3 V. According to the conduction of the selection thyristor 102, the gate voltage of the selection thyristor 102 rises to 3.3 V. This gate voltage is transmitted by the diode 107 and a gate voltage of the selection thyristor 103 changes 1.8 V. However, since a cathode voltage of the selection thyristor 103 is 1.3 V, the selection thyristor 102 maintains the non-conduction state.

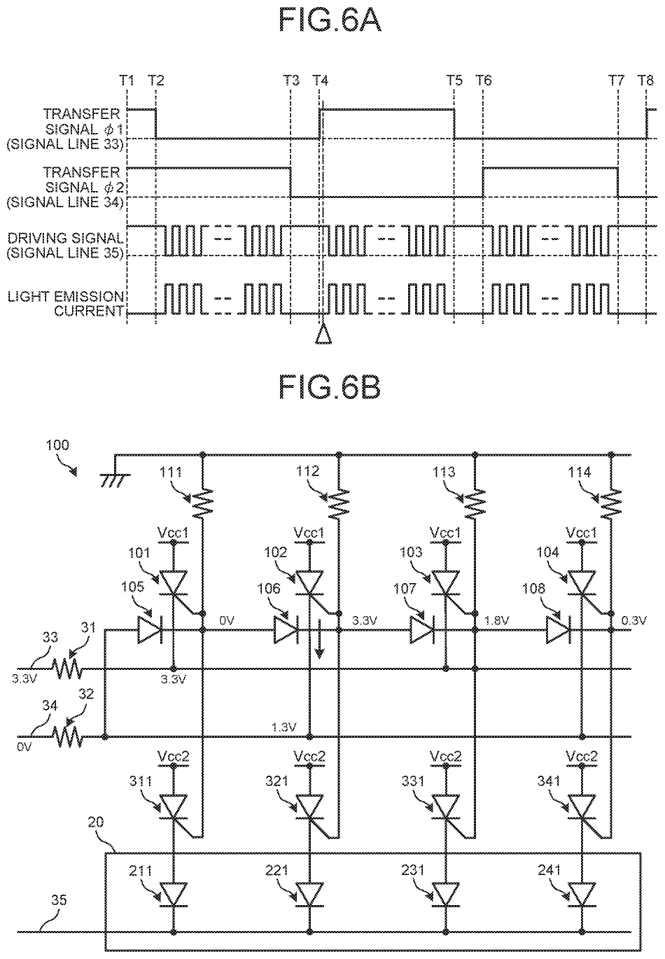

At T4 to T5 (see FIGS. 6A and 6B), the transfer signal ϕ1 changes to 3.3 V. Consequently, the conduction state of the selection thyristor 101 stops. On the other hand, the selection thyristor 102 maintains the conduction state. Since the cathode voltage is 3.3 V, the selection thyristor 103 maintains the non-conduction state.

At T4 to T5, a gate voltage of 3.3 V is applied to the gate of the driving thyristor 321 as a conduction signal and the driving thyristor 321 comes into a conduction state. When a driving signal of 0 V is applied in this state, a light emission current flows to the light emitting element 221 via the driving thyristor 321.

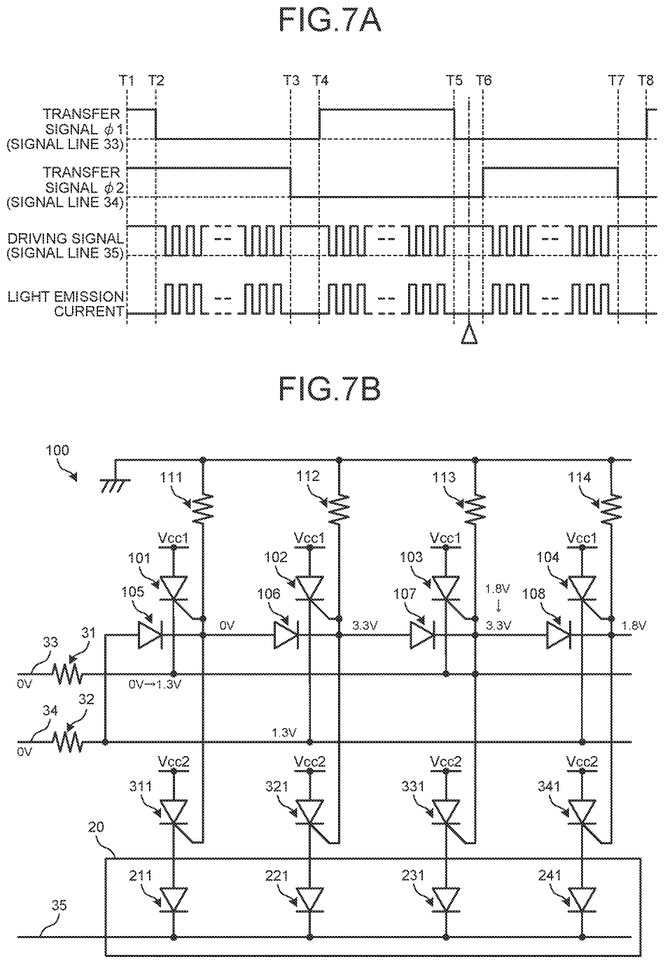

At T5 to T6 (see FIGS. 7A and 7B), since the transfer signal ϕ2 is 0 V, the selection thyristor 102 maintains the conduction state. The transfer signal ϕ1 changes to 0 V. Since the gate voltage is 1.8 V, the selection thyristor 103 comes into a conduction state. Then, since a cathode current of the selection thyristor 103 flows via the resistor 31, the terminal voltage of the resistor 31 rises and the cathode voltage of the selection thyristor 103 rises from 0 V to 1.3 V. According to the conduction of the selection thyristor 103, the gate voltage of the selection thyristor 103 rises to 3.3 V. This gate voltage is transmitted by the diode 108 and a gate voltage of the selection thyristor 104 changes to 1.8 V. However, since a cathode voltage of the selection thyristor 104 is 1.3 V, the selection thyristor 104 maintains a non-conduction state.

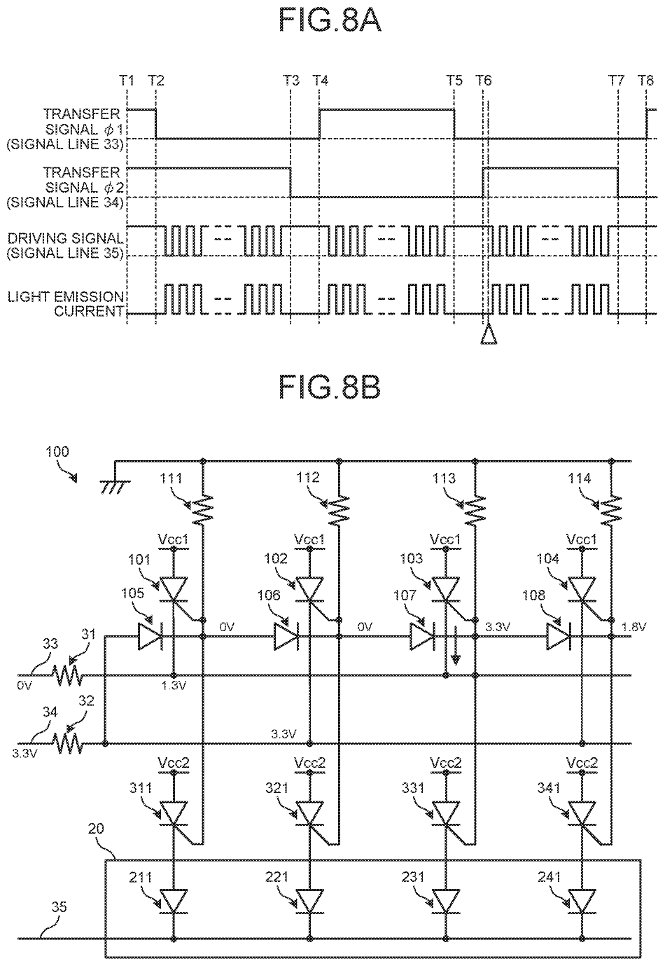

At T6 to T7 (see FIGS. 8A and 8B), the transfer signal ϕ2 changes 3.3 V. Consequently, the conduction state of the selection thyristor 102 stops. On the other hand, the selection thyristor 103 maintains the conduction state. Since the cathode voltage is 3.3 V, the selection thyristor 104 maintains the non-conduction state.

At T6 to T7, a gate voltage of 3.3 V is applied to the gate of the driving thyristor 331 as a conduction signal and the driving thyristor 331 comes into a conduction state. When a driving signal of 0 V is applied in this state, a light emission current flows to the light emitting element 231 via the driving thyristor 331.

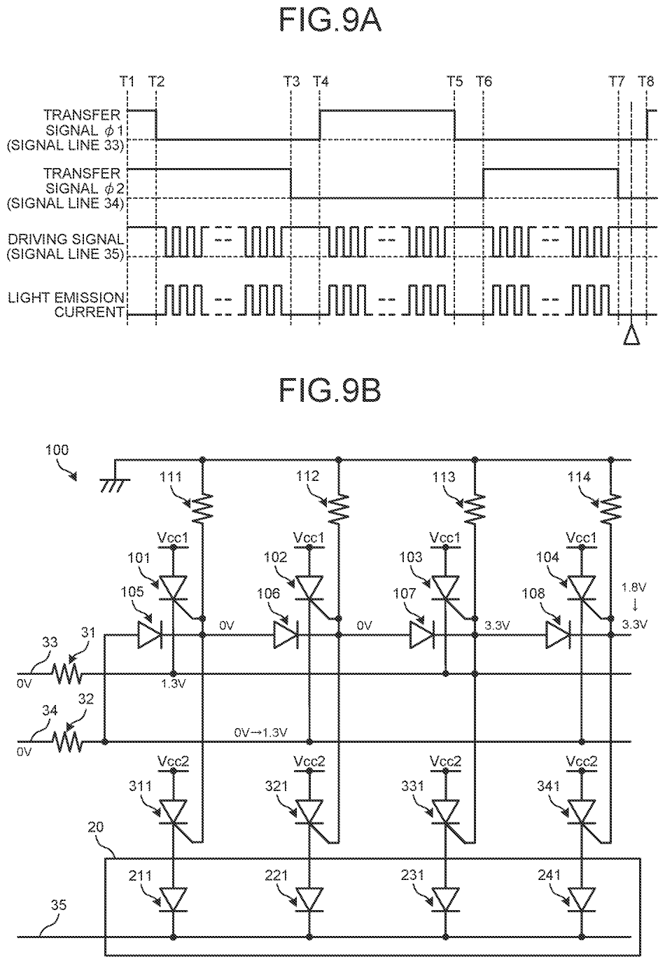

At T7 to T8 (see FIGS. 9A and 9B), since the transfer signal ϕ1 is 0 V, the selection thyristor 103 maintains the conduction state. The transfer signal ϕ1 changes to 0 V. Since the gate voltage is 1.8 V, the selection thyristor 104 comes into a conduction state. Then, the cathode voltage of the selection thyristor 104 rises from 0 V to 1.3 V. According to the conduction of the selection thyristor 104, the gate voltage of the selection thyristor 104 rises to 3.3 V.

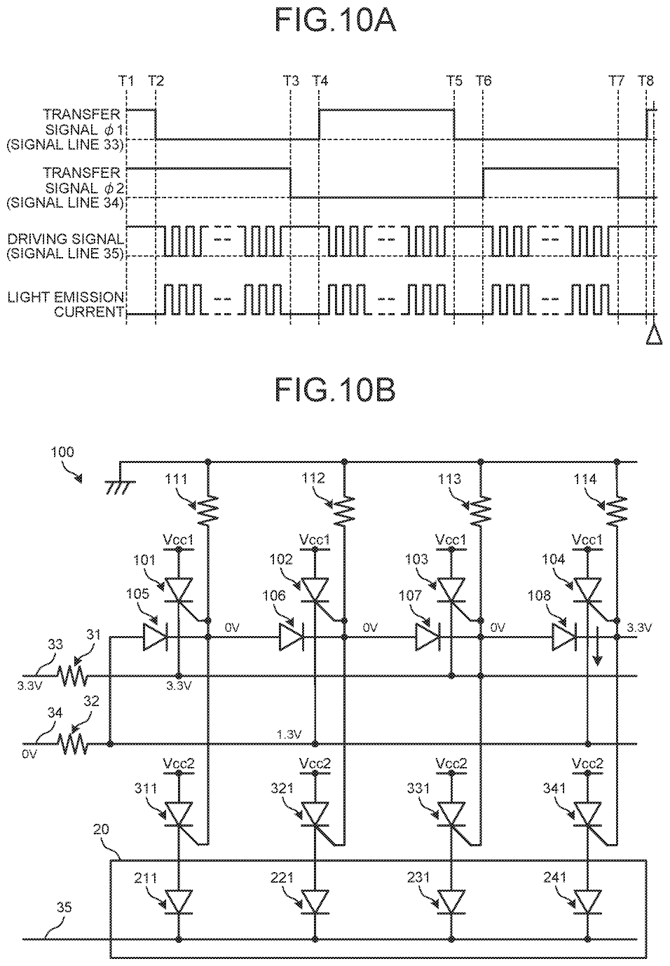

At T8 (see FIGS. 10A and 10B), the transfer signal ϕ1 changes to 3.3 V. Consequently, the conduction state of the selection thyristor 103 stops. On the other hand, the selection thyristor 104 maintains the conduction state. A gate voltage of 3.3 V is applied to a gate of the driving thyristor 341 as a conduction signal and the driving thyristor 341 comes into a conduction state. When a driving signal of 0 V is applied in this state, a light emission current flows to the light emitting element 241 via the driving thyristor 341.

The light emitting unit 20 is driven by the procedure explained above. The periods T1 to T2, T3 to T4, T5 to T6, and T7 to T8 explained above correspond to the transfer period. In a mode in which the positions of the selection thyristors 101 to 104 coming into the conduction state in this selection period are shifted to the right in the figure, the selection thyristor 101 and the like sequentially come into a conduction state. The periods T2 to T3, T4 to T5, and T6 to T7 correspond to the driving period. In this period, any one of the driving thyristors 311, 321, 331, and 341 is selected and comes into a conduction state. By inputting a pulse-like driving signal to the light emitting unit 20, the light emitting element 211 and the like connected to the selected driving thyristor 311 and the like can be caused to emit light.

Note that a period in which the light emitting element 211 and the like are caused to emit light is referred to as light emission period and a period in which the light emitting element 211 and the like are caused to stop the light emission is referred to as non-light emission period. The light emission current supply unit 170 supplies an electric current that alternately repeats the light emission period and the non-light emission period in the driving period.

### 2. First Embodiment

In the light emitting device 10 having the basic configuration explained above, the same conduction current flows to, in the transfer period and the driving period, the selection thyristor 101 and the like that select the driving thyristor 311 and the like. In contrast, the light emitting device 10 according to a first embodiment of the present disclosure is different from the light emitting device 10 having the basic configuration explained above in that a conduction current for the selection thyristor 101 and the like in the driving period is adjusted.

### [Configuration of a Light Emitting Device]

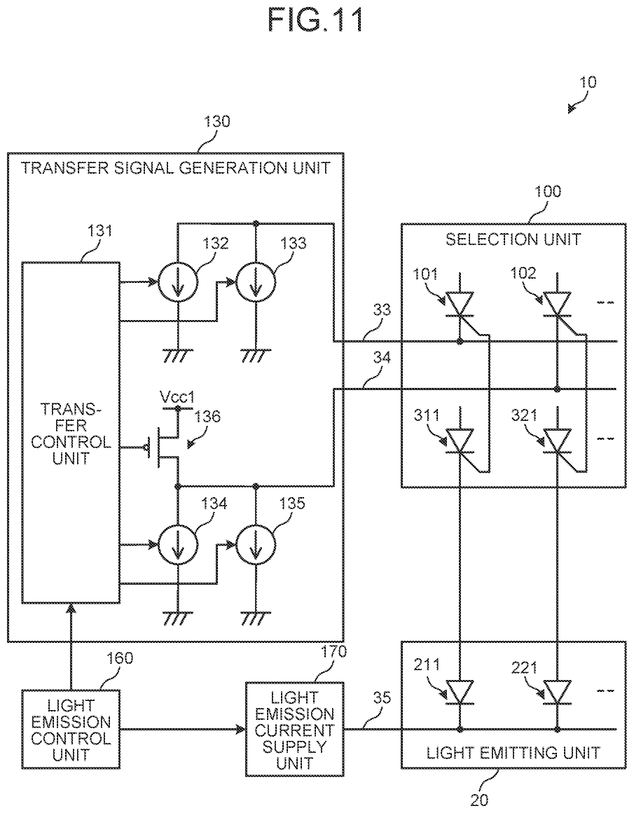

FIG. 11 is a diagram illustrating a configuration example of a light emitting device according to the first embodiment of the present disclosure. Like FIG. 1, the figure is a block diagram illustrating a configuration example of the light emitting device 10. The light emitting device 10 illustrated in FIG. 11 is different from the light emitting device 10 illustrated in FIG. 1 in a configuration of the transfer signal ϕ1. In the light emitting device 10 illustrated in the figure, the resistors 31 and 32 are deleted. Note that description of the selection unit 100 and the light emitting unit 20 illustrated in the figure is simplified.

The transfer signal generation unit 130 illustrated in the figure includes a transfer control unit 131, constant current circuits 132 to 135, and a MOS transistor 136. Note that a p-channel MOS transistor can be used as the MOS transistor 136. Suction side terminals of the constant current circuits 132 and 133 are connected to the signal line 33 in common. Discharge side terminals of the constant current circuits 132 and 133 are grounded. A control signal from the transfer control unit 131 is input to the control terminals of the constant current circuits 132 and 133.

Suction side terminals of the constant current circuits 134 and 135 and a drain of the MOS transistor 136 are connected to the signal line 34 in common. A source of the MOS transistor 136 is connected to the power supply line Vcc1. Discharge side terminals of the constant current circuits 134 and 135 are grounded. A control signal from the transfer control unit 131 is input to control terminals of the constant current circuits 134 and 135 and a gate of the MOS transistor 136.

The constant current circuits 132 to 135 are circuits that feed a constant current. The constant current circuits 133 and 135 are circuits that feed a constant current having a lower value compared with the constant current circuits 132 and 134. The constant current circuits 132 to 135 stop supply of the constant current based on a control signal from the transfer control unit 131. By switching the constant current circuits 132 and 134 and the constant current circuits 133 and 135, an electric current flowing to the signal lines 33 and 34 can be adjusted and a voltage of the cathodes of the selection thyristor 101 and the like can be changed. Note that an electric current supplied by the constant current circuits 133 and 135 can be a current based on a holding current of the selection thyristor 101 and the like. Specifically, the constant current circuits 133 and 135 can adopt, for example, a configuration for feeding an electric current twice as large as the holding current of the selection thyristor 101 and the like.

The MOS transistor 136 is a MOS transistor that supplies a power supply voltage to the signal line 34. The MOS transistor 136 applies a power supply voltage of 3.3 V to the signal line 34 in a period in which the supply of the constant current from the constant current circuits 134 and 135 is stopped. Note that the transfer signal generation unit 130 illustrated in the figure is an example of a current adjustment unit described in the claims.

### [Driving Method]

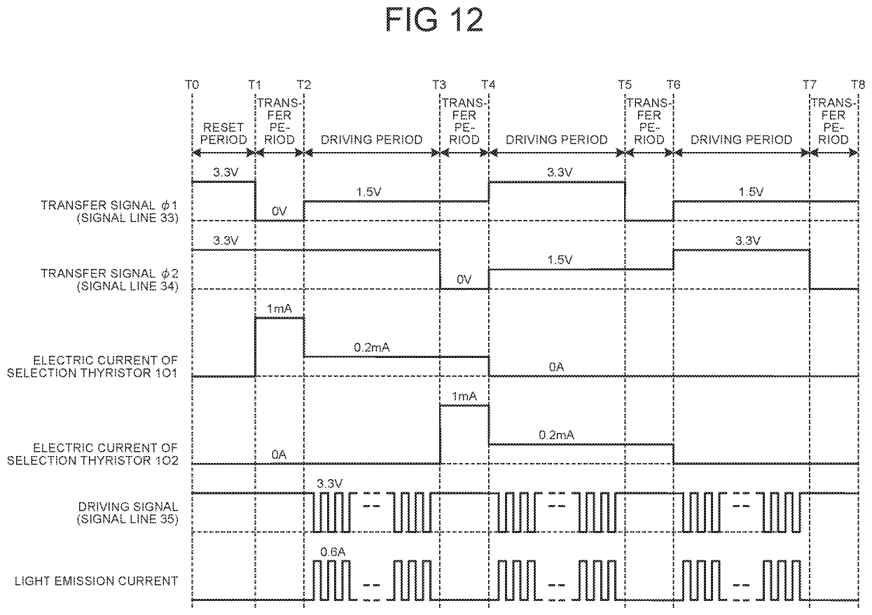

FIG. 12 is a diagram illustrating an example of a driving method according to the first embodiment of the present disclosure. Like FIG. 3A, FIG. 12 is a timing chart illustrating a driving waveform. In the figure, an “electric current of the selection thyristor 101” represents a current waveform of the selection thyristor 101. An “electric current of the selection thyristor 102” represents a current waveform of the selection thyristor 102. Otherwise, the same notations as the notations in FIG. 3A are used.

In a period of T0 to T1, the constant current circuits 132 to 135 stop supply of a constant current. The MOS transistor 136 is made conductive. Consequently, the transfer signal ϕ2 changes to 3.3 V. On the other hand, the transfer signal ϕ1 changes to 3.3 V with the action of the selection thyristor 101. The period of T0 to T1 is equivalent to a reset period.

In a transfer period of T1 to T2, the constant current circuit 132 starts supplying a constant current (1 mA). Consequently, the voltage of the transfer signal ϕ1 changes to 0 V and the selection thyristor 101 becomes conductive. A current of 1 mA flows to the selection thyristor 101. In this period, the selection thyristor 101 is selected. Note that the MOS transistor 136 can be brought into a non-conduction state in a period after T2.

In a driving period of T2 to T3, the selection thyristor 101 maintains the conduction state. At this time, the constant current circuit 132 is controlled to an off state and the constant current circuit 133 supplies a constant current (0.2 mA). Consequently, the voltage of the transfer signal ϕ1 changes 1.5 V, and the electric current of the selection thyristor 101 changes to 0.2 mA. Since the selection thyristor 101 maintains the conduction state, the driving thyristor 311 corresponding to the selection thyristor 101 becomes conductive and a light emission current corresponding to a driving signal flows to the light emitting element 211.

In a transfer period of T3 to T4, the constant current circuit 133 maintains the supply of the constant current (0.2 mA). The selection thyristor 102 becomes conductive and the constant current circuit 134 supplies a constant current (1 mA). Consequently, 0.2 mA flows to the selection thyristor 101 and an electric current of 1 mA flows to the selection thyristor 102.

In a driving period of T4 to T5, the selection thyristor 101 comes into a non-conduction state and the selection thyristor 102 becomes conductive. At this time, the constant current circuits 132 and 133 stop supplying the constant current and the constant current circuit 135 supplies a constant current (0.2 mA). Consequently, the voltage of the transfer signal ϕ2 changes to 1.5 V and the electric current of the selection thyristor 102 changes to 0.2 mA. Since the selection thyristor 102 maintains the conduction state, the driving thyristor 321 corresponding to the selection thyristor 102 becomes conductive and a light emission current corresponding to the driving signal flows to the light emitting element 221. On the other hand, the voltage of the transfer signal ϕ1 changes to 3.3 V and the electric current of the selection thyristor 101 changes to 0 A.

In a transfer period of T5 to T6, the constant current circuit 135 maintains the supply of the constant current (0.2 mA), and a current of 0.2 mA flows through the selection thyristor 102. The constant current circuit 132 starts supplying a constant current (1 mA). Consequently, the voltage of the transfer signal ϕ1 changes to 0 V and the not-illustrated selection thyristor 103 becomes conductive. An electric current of 1 mA flows to the selection thyristor 103.

In the following explanation, an electric current is adjusted in the selection thyristors 103 and 104 as well. It is possible to reduce the electric current of the selection thyristor 101 and the like in the driving period can be reduced. On the other hand, in the transfer period, by feeding a relatively large electric current to the selection thyristor 101 and the like, a transition time to the conduction state and the non-conduction state can be reduced.

### [Another Configuration of the Light Emitting Device]

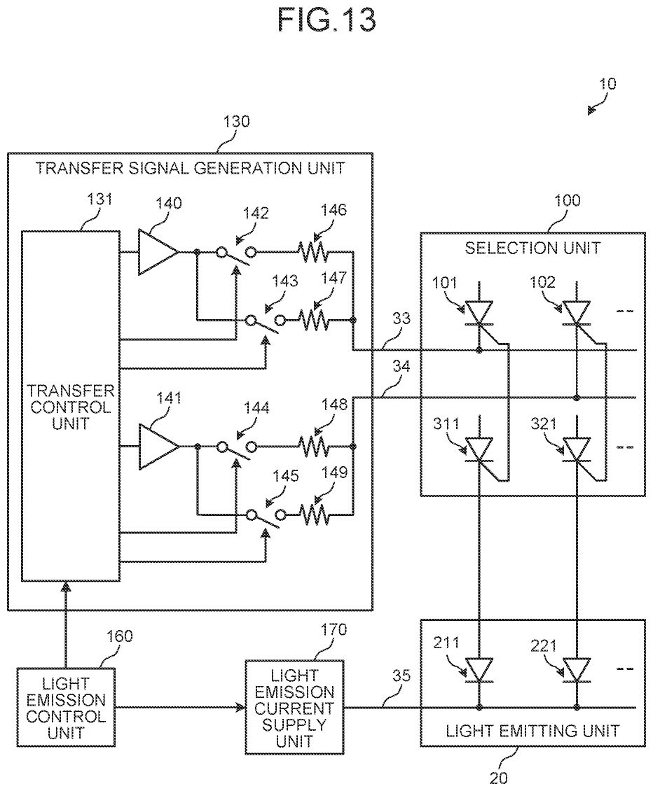

FIG. 13 is a diagram illustrating another configuration example of the light emitting device according to the first embodiment of the present disclosure. Like FIG. 11, FIG. 13 is a block diagram illustrating a configuration example of the light emitting device 10. The light emitting device 10 illustrated in the figure is different from the light emitting device 10 illustrated in FIG. 11 in that an electric current is adjusted by switching resistors instead of the constant current circuit 132 and the like.

The transfer signal generation unit 130 illustrated in the figure includes a transfer control unit 131, amplifiers 140 and 141, switch elements 142 and 144, and resistors 146 to 149. An output of the amplifier 140 is connected to one ends of the switch elements 142 and 143. The other ends of the switch elements 142 and 143 are connected to the signal line 33 respectively via resistors 146 and 147. A control signal from the transfer control unit 131 is transmitted to an input of the amplifier 140 and control inputs of the switch elements 142 and 143. An output of the amplifier 141 is connected to one ends of the switch elements 144 and 145. The other ends of the switch elements 144 and 145 are connected to the signal line 34 respectively via resistors 148 and 149. A control signal from the transfer control unit 131 is transmitted to an input of the amplifier 141 and control inputs of the switch elements 144 and 145.

The amplifiers 140 and 141 output signals of a predetermined voltage based on control of the transfer control unit 131. The amplifiers 140 and 141 illustrated in the figure can output an output voltage of 3.3 V or 0 V. Note that, when the amplifiers 140 and 141 output a voltage of 0 V, a suction current is supplied.

The resistors 146 to 149 are resistors that limit electric currents flowing to the signal line 33 and the signal line 34. The resistors 147 and 149 can be configured to have resistance values higher than those of the resistors 146 and 148.

The switch elements 142 to 145 are elements that become conductive and non-conductive based on a control signal applied to control terminals.

When the switch element 142 is made conductive, an output of the amplifier 140 is connected to the signal line 33 via the resistor 146 having a relatively low value. Therefore, a large current can be fed to the selection thyristor 101 and the like. On the other hand, when the switch element 143 is made conductive, the output of the amplifier 140 is connected to the signal line 33 via the resistor 147 having a relatively high value. Therefore, a relatively small current can be fed to the selection thyristor 101 and the like.

Similarly, when the switch element 144 is made conductive, the output of the amplifier 140 is connected to the signal line 34 via the resistor 148 having a relatively low value. Therefore, a large current can be fed to the selection thyristor 102 and the like. On the other hand, when the switch element 145 is made conductive, the output of the amplifier 140 is connected to the signal line 34 via the resistor 149 having a relatively high value. Therefore, a relatively small current can be fed to the selection thyristor 102 and the like. As explained above, the current of the selection thyristor 101 and the like can be adjusted by switching the resistors 146 to 149 connected in series to the signal lines 33 and 34. Note that the transfer signal generation unit 130 illustrated in the figure is an example of a current adjustment unit described in the claims.

Since components of the light emitting device 10 other than the above are the same as the components of the light emitting device 10 illustrated in FIG. 1 of the present disclosure, explanation of the components is omitted.

As explained above, the light emitting device 10 in the first embodiment of the present disclosure can reduce power consumption by reducing an electric current of the selection thyristor 101 and the like in the driving period.

### 3. Second Embodiment

The light emitting device 10 in the first embodiment explained above reduces the conduction current of the selection thyristor 101 and the like in the driving period. In contrast, the light emitting device 10 in a second embodiment of the present disclosure is different from the light emitting device 10 in the first embodiment explained above in that the selection thyristor 101 and the like in the driving period are brought into a non-conduction state.

### [Configuration of a Light Emitting Device]

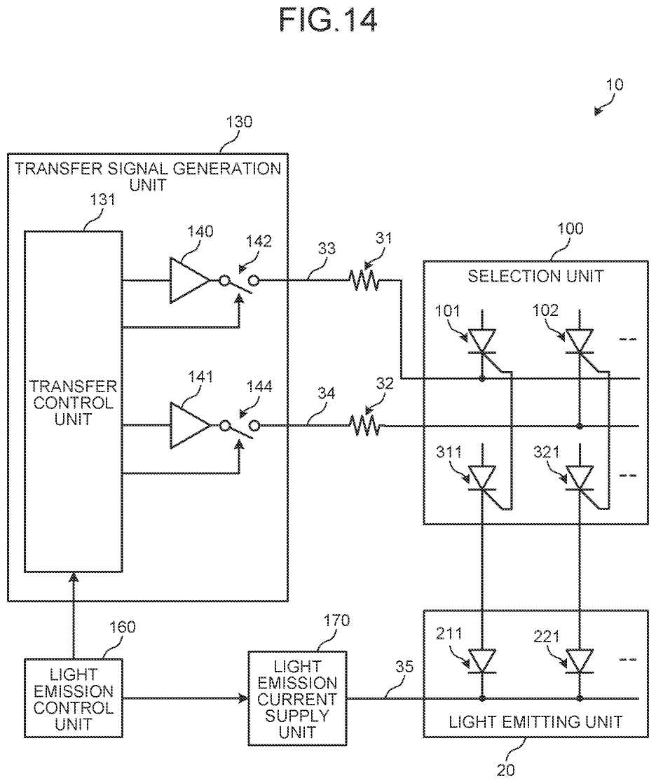

FIG. 14 is a diagram illustrating a configuration example of a light emitting device according to the second embodiment of the present disclosure. Like FIG. 11, FIG. 14 is a block diagram illustrating a configuration example of the light emitting device 10. The light emitting device 10 illustrated in the figure is different from the light emitting device 10 illustrated in FIG. 11 in that the resistors 31 and 32 are connected to the signal lines 33 and 34.

The transfer signal generation unit 130 illustrated in the figure includes a transfer control unit 131, amplifiers 140 and 141, and switch elements 142 and 144. An output of the amplifier 140 is connected to the signal line 33 via the switch element 142. A control signal from the transfer control unit 131 is input to an input of the amplifier 140 and control inputs of the switch element 142. An output of the amplifier 141 is connected to the signal line 34 via the switch element 143. A control signal from the transfer control unit 131 is input to an input of the amplifier 141 and a control input of the switch element 144.

The switch element 142 illustrated in the figure switches conduction and non-conduction between the output of the amplifier 140 and the signal line 33. Similarly, the switch element 144 switches conduction and non-conduction between the output of the amplifier 141 and the signal line 34. By bringing the switch elements 142 and 144 into a non-conduction state, the selection thyristor 101 and the like of the selection unit 100 can be brought into the non-conduction state. This can be performed based on control by the light emission control unit 160 illustrated in the figure.

### [Driving Method]

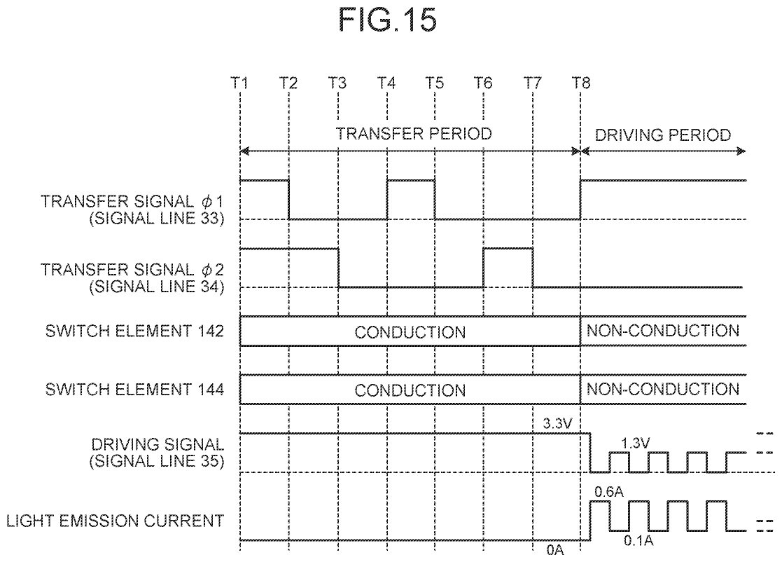

FIG. 15 is a diagram illustrating an example of a driving method according to the second embodiment of the present disclosure. Like FIG. 12, FIG. 15 is a timing chart illustrating a driving waveform. In the figure, “switch element 142” represents a state of the switch element 142. “Switch element 144” represents a state of the switch element 144. Otherwise, the notations as the notations in FIG. 12 are used.

In the light emitting device 10 in the second embodiment of the present disclosure, an operation for selecting the selection thyristor 101 and the like in a desired position is performed in a transfer period. Thereafter, in a state in which the driving thyristor 311 and the like connected to the selected selection thyristor 101 and the like is made conductive, the light emitting device 10 shifts to a driving period and stops the operation of the selection unit 100. The figure illustrates an example in which the selection thyristor 104 and the driving thyristor 341 are selected.

In a transfer period in T1 to T8, the switch elements 142 and 144 are brought into a conduction state to supply the transfer signals ϕ1 and ϕ2 respectively to the signal lines 33 and 34 and the selection thyristor 104 is brought into a conduction state to apply a conduction signal to the gate of the driving thyristor 341. Consequently, the driving thyristor 341 is brought into a conduction state.

In a driving period after T8, the switch elements 142 and 144 are brought into a non-conduction state. Consequently, a conduction current of the selection thyristor 104 is cut off. On the other hand, in order to maintain the conduction state of the driving thyristor 341, a light emission current corresponding to a driving signal flows to the light emitting element 241. Note that the driving signal in the figure supplies a voltage lower than 3.3 V, for example, 1.3 V in a period in which the light emitting element 241 is caused not to emit light. In this case, since an applied voltage to the light emitting element 241 and the like is less than a light emission threshold voltage, the light emitting element 241 and the like do not emit light. On the other hand, a conduction current (0.1 A) equal to or larger than a holding current flows to the driving thyristor 341. Consequently, the conduction state of the driving thyristor 311 and the like in the driving period can be maintained. As explained above, an electric current based on the holding current can be applied to an electric current fed to the driving thyristor 341 and the like in a period in which the light emitting element 241 is caused not to emit light.

Since an electric current of the selection thyristor 101 and the like can be reduced in the driving period, power consumption of the light emitting device 10 can be reduced.

### [Other Driving Methods]

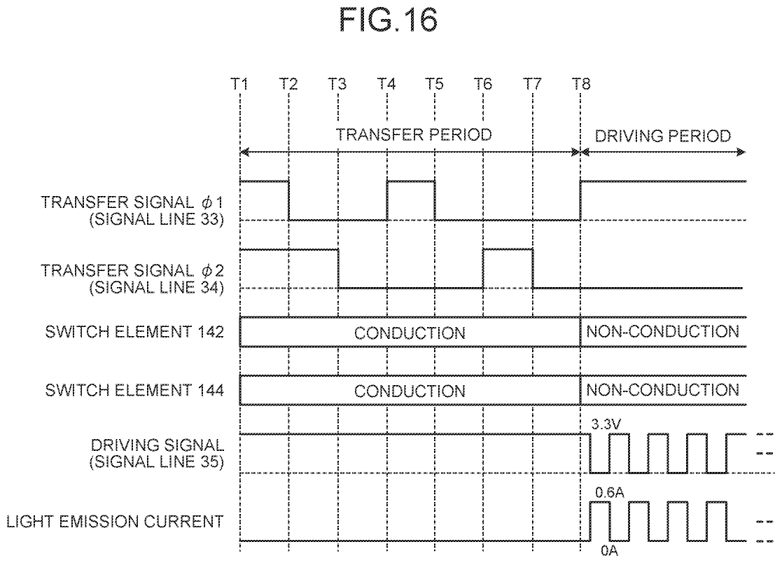

FIG. 16 is a diagram illustrating another example of the driving method according to the second embodiment of the present disclosure. Like FIG. 15, FIG. 16 is a timing chart illustrating a driving waveform. The driving method illustrated in the figure is different from the driving signal in FIG. 15 in the driving period.

In the driving signal illustrated in the figure, 3.3 V is applied in a period in which the light emitting element 241 is caused not to emit light. Therefore, an electric current of the driving thyristor 341 becomes 0 in this period. Usually, a thyristor has action of maintaining a conduction state for a certain period when a conduction current is cut off. When a period in which the conduction state can be maintained is longer than a period in which the light emitting element 241 is caused not to emit light, the holding current explained above can be reduced. Consequently, the power consumption of the light emitting device 10 can be further reduced.

Since components of the light emitting device 10 other than the above are the same as the components of the light emitting device 10 illustrated in FIG. 1 of the present disclosure, explanation of the components is omitted.

As explained above, the light emitting device 10 in the second embodiment of the present disclosure can reduce power consumption by stopping the operation of the selection thyristor 101 and the like in the driving period.

### (4. Configuration of a Distance Measuring Device)

A distance measuring device using the light emitting device 10 is explained.

### [Configuration of the Distance Measuring Device]

FIG. 17 is a diagram illustrating a configuration example of the distance measuring device according to the embodiment of the present disclosure. The distance measuring device 701 illustrated in the figure includes a light emitting unit 702, a driving unit 703, a power supply circuit 704, a light-emitting side optical system 705, a light-receiving side optical system 706, a light receiving unit 707, a signal processing unit 708, a control unit 709, and a temperature detecting unit 710.

The light emitting unit 702 emits light using a plurality of light sources. As explained below, the light emitting unit 702 of the present example includes light emitting elements 2a by VCSEL (Vertical Cavity Surface Emitting LASER) as the light sources and is configured by the light emitting elements 2a being arrayed in a predetermined mode such as a matrix.

The driving unit 703 includes a power supply circuit 704 for driving the light emitting unit 702. The power supply circuit 704 generates a power supply voltage (a drive voltage Vd explained below) of the driving unit 703 based on, for example, an input voltage (an input voltage Vin explained below) from a not-illustrated battery or the like provided in the distance measuring device 701. The driving unit 703 drives the light emitting unit 702 on based on the power supply voltage.

A subject S serving as a distance measurement target is irradiated with, via the light-emitting side optical system 705, light emitted from the light emitting unit 702. Then, reflected light from the subject S of the light emitted as explained above is made incident on the light receiving surface of the light receiving unit 707 via the light-receiving side optical system 706.

The light receiving unit 707 is a light receiving element such as a CCD (Charge Coupled Device) sensor or a CMOS (Complementary Metal Oxide Semiconductor) sensor, receives the reflected light from the subject S made incident via the light-receiving side optical system 706 as explained above, converts the reflected light into an electric signal, and outputs the electric signal. The light receiving unit 707 executes, for an electric signal obtained by photoelectrically converting received light, for example, CDS (Correlated Double Sampling) processing or AGC (Automatic Gain Control) processing and further performs A/D (Analog/Digital) conversion processing. Then, a signal serving as digital data is output to the signal processing unit 8 in a later stage.

The light receiving unit 707 of the present example outputs a frame synchronization signal Fs to the driving unit 703. Consequently, the driving unit 703 is capable of causing the light emitting element 2a in the light emitting unit 702 to emit light at timing corresponding to a frame period of the light receiving unit 707.

The signal processing unit 8 is configured as a signal processing processor using, for example, a DSP (Digital Signal Processor). The signal processing unit 708 applies various kinds of signal processing to a digital signal input from the light receiving unit 707.

The control unit 709 includes, for example, a microcomputer including a CPU (Central Processing Unit), a ROM (Read Only Memory), a RAM (Random Access Memory) or an information processing device such as a DSP and performs control of the driving unit 703 for controlling a light emission operation by the light emitting unit 702 and control relating to a light reception operation by the light receiving unit 707.

The control unit 709 has a function of a distance measuring unit 709a. The distance measuring unit 709a measures the distance to the subject S based on a signal input via the signal processing unit 708 (that is, a signal obtained by receiving reflected light from the subject S). The distance measuring unit 709a of the present example measures distances for parts of the subject S in order to make it possible to specify a three-dimensional shape of the subject S. Here, a specific distance measuring method in the distance measuring device 701 is explained below again.

The temperature detecting unit 710 detects the temperature of the light emitting unit 702. As the temperature detecting unit 710, for example, a configuration for performing temperature detection using a diode can be adopted. In the present example, information concerning the temperature detected by the temperature detecting unit 710 is supplied to the driving unit 703, whereby the driving unit 703 can drive the light emitting unit 702 based on the information concerning the temperature.

### [Distance Measuring Method]

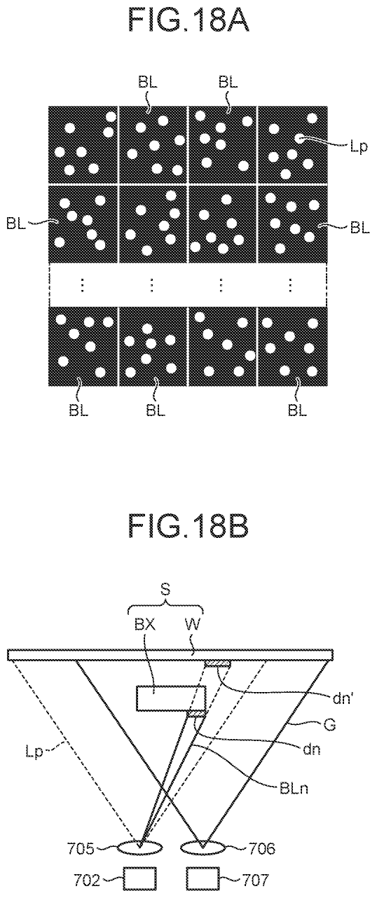

FIGS. 18A and 18B are diagrams illustrating an example of a distance measuring method according to an embodiment of the present disclosure. As a distance measuring method in the distance measuring device 701, for example, a distance measuring method by an STL (Structured Light) method or a ToF (Time of Flight) method can be adopted.

The STL method is a method for measuring a distance based on an image of the subject S irradiated with light having a predetermined light/dark pattern such as a dot pattern or a lattice pattern. FIG. 18 is an explanatory diagram of the STL method.

In the STL method, for example, the subject S is irradiated with pattern light Lp by a dot pattern illustrated in FIG. 18A. The pattern light Lp is divided into a plurality of blocks BL. Different dot patterns are allocated to the blocks BL (such that the dot patterns do not overlap among the blocks B).

FIG. 18B is an explanatory diagram of a distance measurement principle of the STL method. Here, as an example, a wall W and a box BX disposed in front of the wall W are the subject S and the subject S is irradiated with the pattern light Lp. “G” in the figure schematically represents an angle of view by the light receiving unit 707. “BLn” in the figure means light of a certain block BL in the pattern light Lp and “dn” means a dot pattern of the block BLn reflected on a light reception image by the light receiving unit 707. Here, when the box BX in front of the wall W is absent, the dot pattern of the block BLn is reflected in a position of “dn′” in the figure in the light reception image. That is, a position where a pattern of the block BLn is reflected in the light reception image is different between when the box BX is present and when the box BX is absent, and specifically, pattern distortion occurs.

The STL method is a method for calculating a shape and depth of the subject S making use of the fact that the pattern irradiated as explained above is distorted by an object shape of the subject S. Specifically, the STL method is a method for calculating a shape and depth of the subject S from a state of pattern distortion.

When the STL method is adopted, for example, an IR (Infrared) light receiving unit by a global shutter method is used as the light receiving unit 707. In the case of the STL method, the distance measuring unit 709a controls the driving unit 703 such that the light emitting unit 702 emits pattern light, detects distortion of a pattern for an image signal obtained via the signal processing unit 708, and calculates a distance based on the distortion of the pattern.

Subsequently, the ToF method is a method for measuring the distance to an object by detecting a flight time (time difference) of light emitted by the light emitting unit 702 until the light is reflected by the object and reaches the light receiving unit 707.

When a so-called direct ToF (dToF) method is adopted as the ToF method, an SPAD (Single Photon Avalanche Diode) is used as the light receiving unit 707 and the light emitting unit 702 is pulse-driven. In this case, the distance measuring unit 709a calculates, based on a signal input via the signal processing unit 708, a time difference between light emission and light reception for light emitted from the light emitting unit 702 and received by the light receiving unit 707 and calculates distances to the parts of the subject S based on the time difference and the speed of light. Note that, when a so-called indirect ToF (iToF) method (a phase difference method) is adopted as the ToF method, for example, a light receiving unit that can receive IR is used as the light receiving unit 707.

The light emitting device 10 illustrated in FIG. 11 and the like can be used for the light emitting unit 702 illustrated in FIG. 17. Note that an electric signal output by the light receiving unit 707 corresponds to the light reception signal.

### Effects

The light emitting device 10 includes a plurality of light emitting elements (the light emitting element 211 and the like), a plurality of driving thyristors (the driving thyristor 311 and the like), the selection unit 100, the light emission current supply unit 170, and a current adjustment unit (the transfer signal generation unit 130). The driving thyristors are disposed for each of the plurality of light emitting elements and become conductive themselves to thereby feed a light emission current to the light emitting elements ad drive the light emitting elements. The selection unit 100 includes a plurality of selection thyristors (the selection thyristor 101 and the like) that are disposed for each of the plurality of driving thyristors and output a conduction signal for making the driving thyristors conductive when the selection thyristors become conductive themselves. The selection unit 100 alternately repeats a transfer period in which the plurality of driving thyristors are sequentially selected by shifting, in order, the position of the selection thyristor coming into a conduction state among the plurality of selection thyristors and a driving period in which the selected driving thyristor is caused to drive the light emitting element. The light emission current supply unit 170 supplies a light emission current to the light emitting element via the selected driving thyristor in the driving period. The current adjustment unit (the transfer signal generation unit 130) supplies a conduction current of the selection thyristor and adjusts the conduction current of the selection thyristor in the driving period. By adjusting an electric current of the selection thyristor, power consumption of the light emitting device 10 can be reduced.

The current adjustment unit (the transfer signal generation unit 130) may adjust the conduction current based on a holding current of the selection thyristor. Consequently, it is possible to prevent the selection thyristor from shifting to the non-conduction state.

The light emission current supply unit 170 may supply a light emission current in a light emission period in which the light emitting element is caused to emit light and may stop the supply of the light emission current in a non-light emission period in which the light emission of the light emitting element is stopped. Consequently, pulse-like light emission can be obtained.

The light emission current supply unit 170 may alternately repeat the light emission period and the non-light emission period. Consequently, pulse train-like light emission can be obtained.

The light emitting device 10 may include a plurality of light emitting element groups (the light emitting element group 211 and the like) configured by a plurality of light emitting elements, the driving thyristors may be disposed for each of the light emitting elements of each of the plurality of light emitting element groups, and the selection thyristors may be disposed for each of the light emitting element groups and output a conduction signal in common to the plurality of driving thyristors of the light emitting element groups. Consequently, the plurality of light emitting elements can be driven in common.

The distance measuring device 701 includes the light emitting device 10, the light receiving unit 707, and the distance measuring unit 709a. The light emitting device 10 includes a plurality of light emitting elements (the light emitting element 211 and the like), a plurality of driving thyristors (the driving thyristor 311 and the like), the selection unit 100, the light emission current supply unit 170, and a current adjustment unit (the transfer signal generation unit 130). The driving thyristors are disposed for each of the plurality of light emitting elements and become conductive themselves to thereby feed a light emission current to the light emitting elements ad drive the light emitting elements. The selection unit 100 includes a plurality of selection thyristors (the selection thyristor 101 and the like) that are disposed for each of the plurality of driving thyristors and output a conduction signal for making the driving thyristors conductive when the selection thyristors become conductive themselves. The selection unit 100 alternately repeats a transfer period in which the plurality of driving thyristors are sequentially selected by shifting, in order, the position of the selection thyristor coming into a conduction state among the plurality of selection thyristors and a driving period in which the selected driving thyristor is caused to drive the light emitting element. The light emission current supply unit 170 supplies a light emission current to the light emitting element via the selected driving thyristor in the driving period. The current adjustment unit (the transfer signal generation unit 130) supplies a conduction current of the selection thyristor and adjusts the conduction current of the selection thyristor in the driving period. The light receiving unit 707 receives reflected light of light from the light emitting element reflected by an object and generates a light reception signal. The distance measuring unit 709a measures the distance to the object based on the light reception signal. By adjusting an electric current of the selection thyristor, power consumption of the distance measuring device 701 can be reduced.

The light emitting device 10 includes a plurality of light emitting elements (the light emitting element 211 and the like), a plurality of driving thyristors (the driving thyristor 311 and the like), the selection unit 100, the light emission current supply unit 170, and a control unit. The driving thyristors are disposed for each of the plurality of light emitting elements and become conductive themselves to thereby feed a light emission current to the light emitting elements ad drive the light emitting elements. The selection unit 100 includes a plurality of selection thyristors (the selection thyristor 101 and the like) that are disposed for each of the plurality of driving thyristors and output a conduction signal for making the driving thyristors conductive when the selection thyristors become conductive themselves. The selection unit 100 alternately repeats a transfer period in which the plurality of driving thyristors are sequentially selected by shifting, in order, the position of the selection thyristor coming into a conduction state among the plurality of selection thyristors and a driving period in which the selected driving thyristor is caused to drive the light emitting element. The light emission current supply unit 170 supplies a light emission current to the light emitting element via the selected driving thyristor in the driving period. The control unit performs control for stopping the supply of the conduction current to the selection thyristor in the driving period. By stopping the supply of the conduction current to the selection thyristor in the driving period, power consumption of the light emitting device 10 can be reduced.

The light emission current supply unit 170 may supply a light emission current in a light emission period in which the light emitting element is caused to emit light and may stop the supply of the light emission current in a non-light emission period in which the light emission of the light emitting element is stopped. Consequently, pulse-like light emission can be obtained.

The light emission current supply unit 170 may alternately repeat the light emission period and the non-light emission period. Consequently, pulse train-like light emission can be obtained.

The light emission current supply unit 170 may supply an electric current based on a holding current of the driving thyristor in the non-light emission period. Consequently, it is possible to prevent the driving thyristor from shifting to the non-conduction state.

The light emitting device 10 may include a plurality of light emitting element groups (the light emitting element group 211 and the like) configured by a plurality of light emitting elements, the driving thyristors may be disposed for each of the light emitting elements of each of the plurality of light emitting element groups, and the selection thyristors may be disposed for each of the light emitting element groups and output a conduction signal in common to the plurality of driving thyristors of the light emitting element groups. Consequently, the plurality of light emitting elements can be driven in common.

The distance measuring device 701 includes the light emitting device 10, the light receiving unit 707, and the distance measuring unit 709a. The light emitting device 10 includes a plurality of light emitting elements (the light emitting element 211 and the like), a plurality of driving thyristors (the driving thyristor 311 and the like), the selection unit 100, the light emission current supply unit 170, and a control unit. The driving thyristors are disposed for each of the plurality of light emitting elements and become conductive themselves to thereby feed a light emission current to the light emitting elements ad drive the light emitting elements. The selection unit 100 includes a plurality of selection thyristors (the selection thyristor 101 and the like) that are disposed for each of the plurality of driving thyristors and output a conduction signal for making the driving thyristors conductive when the selection thyristors become conductive themselves. The selection unit 100 alternately repeats a transfer period in which the plurality of driving thyristors are sequentially selected by shifting, in order, the position of the selection thyristor coming into a conduction state among the plurality of selection thyristors and a driving period in which the selected driving thyristor is caused to drive the light emitting element. The light emission current supply unit 170 supplies a light emission current to the light emitting element via the selected driving thyristor in the driving period. The control unit performs control for stopping the supply of the conduction current to the selection thyristor in the driving period. The light receiving unit 707 receives reflected light of light from the light emitting element reflected by an object and generates a light reception signal. The distance measuring unit 709a measures the distance to the object based on the light reception signal. By stopping the supply of the conduction current to the selection thyristor in the driving period, power consumption of the distance measuring device 701 can be reduced.

Note that the effects described in this specification are only illustrations and are not limited. Other effects may be present.

Note that the present technology can also take the following configurations.

(1)

A light emitting device comprising:
a plurality of light emitting elements;
a plurality of driving thyristors that are disposed for each of the plurality of light emitting elements and become conductive themselves to thereby feed a light emission current to the light emitting elements and drive the light emitting elements;
a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor;
a light emission current supply unit that supplies the light emission current to the light emitting element via the selected driving thyristor in the driving period; and a current adjustment unit that supplies a conduction current of the selection thyristor and adjusts the conduction current of the selection thyristor in the driving period.
   (2)

The light emitting device according to the above (1), wherein the current adjustment unit adjusts the conduction current based on a holding current of the selection thyristor.

(3)

The light emitting device according to the above (1) or (2), wherein the light emission current supply unit supplies the light emission current in a light emission period in which the light emitting element is caused to emit light and stops the supply of the light emission current in a non-light emission period in which the light emission of the light emitting element is stopped.

(4)

The light emitting device according to the above (3), wherein the light emission current supply unit alternately repeats the light emission period and the non-light emission period.

(5)

The light emitting device according to any one of the above (1) to (4), wherein
the light emitting device includes a plurality of light emitting element groups configured by the plurality of light emitting elements,
the driving thyristors are disposed for each of the light emitting elements of each of the plurality of light emitting element groups, and
the selection thyristors are disposed for each of the light emitting element groups and output the conduction signal to the plurality of driving thyristors of the light emitting element group in common.
   (6)

A distance measuring device comprising:
a light emitting device including:
a plurality of light emitting elements;
a plurality of driving thyristors that are disposed for each of the plurality of light emitting elements and become conductive themselves to thereby feed a light emission current to the light emitting elements and drive the light emitting elements;
a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor;
a light emission current supply unit that supplies the light emission current to the light emitting element via the selected driving thyristor in the driving period; and
a current adjustment unit that supplies a conduction current of the selection thyristor and adjusts the conduction current of the selection thyristor in the driving period;
a light receiving unit that receives reflected light of light from the light emitting element reflected by an object and generates a light reception signal; and
a distance measuring unit that measures a distance to the object based on the light reception signal.
   (7)

A light emitting device comprising:
a plurality of light emitting elements;
a plurality of driving thyristors that are disposed for each of the plurality of light emitting elements and become conductive themselves to thereby feed a light emission current to the light emitting elements and drive the light emitting elements;
a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor;
a light emission current supply unit that supplies the light emission current to the light emitting element via the selected driving thyristor in the driving period; and
a control unit that performs control for stopping the supply of the conduction current to the selection thyristor in the driving period.
   (8)

The light emitting device according to the above (7), wherein the light emission current supply unit supplies the light emission current in a light emission period in which the light emitting element is caused to emit light and stops the supply of the light emission current in a non-light emission period in which the light emission of the light emitting element is stopped.

(9)

The light emitting device according to the above (8), wherein the light emission current supply unit alternately repeats the light emission period and the non-light emission period.

(10)

The light emitting device according to the above (8), wherein the light emission current supply unit supplies an electric current based on a holding current of the driving thyristor in the non-light emission period.

(11)

The light emitting device according to any one of the above (7) to (10), wherein
the light emitting device includes a plurality of light emitting element groups configured by the plurality of light emitting elements,
the driving thyristors are disposed for each of the light emitting elements of each of the plurality of light emitting element groups, and
the selection thyristors are disposed for each of the light emitting element groups and output the conduction signal to the plurality of driving thyristors of the light emitting element group in common.
   (12)

A distance measuring device comprising:
a light emitting device including:
a plurality of light emitting elements;
a plurality of driving thyristors that are disposed for each of the plurality of light emitting elements and become conductive themselves to thereby feed a light emission current to the light emitting elements and drive the light emitting elements;
a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor;
a light emission current supply unit that supplies the light emission current to the light emitting element via the selected driving thyristor in the driving period; and
a control unit that performs control for stopping the supply of the conduction current to the selection thyristor in the driving period;
a light receiving unit that receives reflected light of light from the light emitting element reflected by an object and generates a light reception signal; and
a distance measuring unit that measures a distance to the object based on the light reception signal.

### REFERENCE SIGNS LIST

10 LIGHT EMITTING DEVICE
20, 702 LIGHT EMITTING UNIT
100 SELECTION UNIT
101 to 104 SELECTION THYRISTOR
130 TRANSFER SIGNAL GENERATION UNIT
131 TRANSFER CONTROL UNIT
132 to 135 CONSTANT CURRENT CIRCUIT
31, 32, 146 to 149 RESISTOR
160 LIGHT EMISSION CONTROL UNIT
170 LIGHT EMISSION CURRENT SUPPLY UNIT
210, 220, 230, 240 LIGHT EMITTING ELEMENT GROUP
211 to 214, 221 to 224, 231 to 234, 241 to 244 LIGHT EMITTING ELEMENT
311 to 314, 321 to 324, 331 to 334, 341 to 344 DRIVING THYRISTOR
701 DISTANCE MEASURING DEVICE
703 DRIVING UNIT
707 LIGHT RECEIVING UNIT
708 SIGNAL PROCESSING UNIT
709a DISTANCE MEASURING UNIT

1. A light emitting device comprising:
a plurality of light emitting elements;
a plurality of driving thyristors that are disposed for each of the plurality of light emitting elements and become conductive themselves to thereby feed a light emission current to the light emitting elements and drive the light emitting elements;
a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor;
a light emission current supply unit that supplies the light emission current to the light emitting element via the selected driving thyristor in the driving period; and
a current adjustment unit that supplies a conduction current of the selection thyristor and adjusts the conduction current of the selection thyristor in the driving period.

2. The light emitting device according to claim 1, wherein the current adjustment unit adjusts the conduction current based on a holding current of the selection thyristor.

3. The light emitting device according to claim 1, wherein the light emission current supply unit supplies the light emission current in a light emission period in which the light emitting element is caused to emit light and stops the supply of the light emission current in a non-light emission period in which the light emission of the light emitting element is stopped.

4. The light emitting device according to claim 3, wherein the light emission current supply unit alternately repeats the light emission period and the non-light emission period.

5. The light emitting device according to claim 1, wherein
the light emitting device includes a plurality of light emitting element groups configured by the plurality of light emitting elements,
the driving thyristors are disposed for each of the light emitting elements of each of the plurality of light emitting element groups, and
the selection thyristors are disposed for each of the light emitting element groups and output the conduction signal to the plurality of driving thyristors of the light emitting element group in common.

6. A distance measuring device comprising:
a light emitting device including:
a plurality of light emitting elements;
a plurality of driving thyristors that are disposed for each of the plurality of light emitting elements and become conductive themselves to thereby feed a light emission current to the light emitting elements and drive the light emitting elements;
a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor;
a light emission current supply unit that supplies the light emission current to the light emitting element via the selected driving thyristor in the driving period; and
a current adjustment unit that supplies a conduction current of the selection thyristor and adjusts the conduction current of the selection thyristor in the driving period;
a light receiving unit that receives reflected light of light from the light emitting element reflected by an object and generates a light reception signal; and
a distance measuring unit that measures a distance to the object based on the light reception signal.

7. A light emitting device comprising:
a plurality of light emitting elements;
a plurality of driving thyristors that are disposed for each of the plurality of light emitting elements and become conductive themselves to thereby feed a light emission current to the light emitting elements and drive the light emitting elements;
a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor;
a light emission current supply unit that supplies the light emission current to the light emitting element via the selected driving thyristor in the driving period; and
a control unit that performs control for stopping the supply of the conduction current to the selection thyristor in the driving period.

8. The light emitting device according to claim 7, wherein the light emission current supply unit supplies the light emission current in a light emission period in which the light emitting element is caused to emit light and stops the supply of the light emission current in a non-light emission period in which the light emission of the light emitting element is stopped.

9. The light emitting device according to claim 8, wherein the light emission current supply unit alternately repeats the light emission period and the non-light emission period.

10. The light emitting device according to claim 8, wherein the light emission current supply unit supplies an electric current based on a holding current of the driving thyristor in the non-light emission period.

11. The light emitting device according to claim 7, wherein
the light emitting device includes a plurality of light emitting element groups configured by the plurality of light emitting elements,
the driving thyristors are disposed for each of the light emitting elements of each of the plurality of light emitting element groups, and
the selection thyristors are disposed for each of the light emitting element groups and output the conduction signal to the plurality of driving thyristors of the light emitting element group in common.

12. A distance measuring device comprising:
a light emitting device including:
a plurality of light emitting elements;
a plurality of driving thyristors that are disposed for each of the plurality of light emitting elements and become conductive themselves to thereby feed a light emission current to the light emitting elements and drive the light emitting elements;
a selection unit including a plurality of selection thyristors that are disposed for each of the plurality of driving thyristors and output a conduction signal for making the driving thyristors conductive when the selection thyristors become conductive themselves and alternately repeats a transfer period in which the plurality of driving thyristors are sequentially selected by shifting, in order, a position of the selection thyristor coming into a conduction state among the plurality of selection thyristors and a driving period in which the light emitting element is driven by the selected driving thyristor;
a light emission current supply unit that supplies the light emission current to the light emitting element via the selected driving thyristor in the driving period; and
a control unit that performs control for stopping the supply of the conduction current to the selection thyristor in the driving period;
a light receiving unit that receives reflected light of light from the light emitting element reflected by an object and generates a light reception signal; and
a distance measuring unit that measures a distance to the object based on the light reception signal.
